(19) United States
(12) Patent Application Publication
(10) Pub. No.: US 2012/0112225 A1
(43) Pub. Date: May 10, 2012

(54) METHOD FOR PRODUCING AN ORGANIC LIGHT-EMITTING DIODE DEVICE HAVING A STRUCTURE WITH A TEXTURED SURFACE AND RESULTING OLED HAVING A STRUCTURE WITH A TEXTURED SURFACE

(75) Inventors: David Le Bellac, Antibes (FR); Bernard Nghiem, Arsy (FR); François-Julien Vermersch, Paris (FR)

(73) Assignee: SAINT-GOBAIN GLASS FRANCE, Courbevoie (FR)

(21) Appl. No.: 13/260,987

(22) PCT Filed: Apr. 2, 2010
(86) PCT No.: PCT/FR2010/050641

§ 371 Date: Jan. 23, 2012

(30) Foreign Application Priority Data
Apr. 2, 2009 (FR) 0952154

(51) Int. Cl. H01L 33/58; H01L 51/52

(52) U.S. Cl. 257/98; 438/29; 257/E33.073

(57) ABSTRACT

A process for manufacturing an organic light-emitting diode device bearing a structure having a textured outer surface including a substrate made of inorganic glass that forms the support of the organic light-emitting diode device, includes: manufacturing the structure having a textured outer surface including: vapor depositing, onto the substrate made of inorganic glass, a first dielectric layer of at least 300 nm in thickness at a temperature greater than or equal to 100° C. so as to form protrusions, depositing onto the first layer a second smoothing dielectric layer, having a refractive index greater than or equal to that of the first layer, and made of an essentially amorphous material so as to sufficiently smooth the protrusions and to form the textured outer surface, and depositing, directly onto the smoothing layer, an electrode in the form of layer(s), so as to form a surface that conforms substantially to the smoothed outer surface.

The invention relates to a process for manufacturing an organic light-emitting diode device with a surface-textured structure comprising a substrate made of inorganic glass, forming the support of the organic light-emitting diode device and also an organic light-emitting diode device with such a structure.

An OLED, or organic light-emitting diode, comprises an organic light-emitting material or a multilayer of organic light-emitting materials, and is framed by two electrodes, one of the electrodes, generally the anode, consisting of that associated with the glass substrate and the other electrode, the cathode, being arranged on the organic materials, on the opposite side from the anode.

The OLED is a device that emits light via electroluminescence using the recombination energy of holes injected from the anode and electrons injected from the cathode. In the case where the anode is transparent, the emitted photons pass through the transparent anode and the glass substrate supporting the OLED so as to supply light beyond the device.

OLEDs are generally used in display screens or more recently in an in particular general lighting device, with different constraints.

For a general lighting system, the light extracted from the OLED is “white” light because certain or even all of the wavelengths of the spectrum are emitted. The light must furthermore be emitted uniformly. In this respect a Lambertian emission is more precisely spoken of, i.e. obeying Lambert's law, and characterized by a photometric luminance that is equal in all directions.

Moreover, OLEDs have low light-extraction efficiency: the ratio between the light that actually exits from the glass substrate and that emitted by the light-emitting materials is relatively low, about 0.25.

This phenomenon is especially explained by the fact that a certain number of photons remain trapped between the cathode and the anode.

Solutions are therefore sought to improve the efficiency of OLEDs, namely to increase the extraction efficiency while supplying white light that is as uniform as possible. The term “uniform” is, in the remainder of the description, understood to mean uniform in intensity, color and in space.

It is known to provide, at the substrate-anode interface, a periodically protruding structure that forms a diffraction grating and thus increases the extraction efficiency.

Document U.S 2004/0227462 specifically shows an OLED the transparent substrate of which, supporting the anode and the organic layer, is textured. The surface of the substrate thus comprises an alternation of protrusions and troughs, the profile of which is followed by the anode and the organic layer that are deposited thereon. The profile of the substrate is obtained by applying a photoresist mask to the surface of the substrate, the pattern of the mask corresponding to that sought for the protrusions, and then etching the surface through the mask. However, such a process is not easy to implement industrially over large substrate areas, and is above all too expensive, especially for lighting applications.

Furthermore, electrical defects are observed in the OLEDs.

One objective of the invention is therefore a process for manufacturing a support for an OLED that simultaneously provides increased extraction efficiency over a wide range of wavelengths, a sufficiently uniform white light and increased reliability.

According to the invention, the process for manufacturing an organic light-emitting diode device with a structure having a textured outer surface comprising a substrate made of inorganic glass, forming the support of the organic light-emitting diode device, which comprises:
the manufacture of said structure having a textured outer surface comprising:
   the deposition, onto the inorganic glass substrate, of a first dielectric layer having a thickness of at least 300 nm, preferably greater than 500 nm, or even greater than 1 μm, at a temperature greater than or equal to 100° C. so as to form protrusions (and therefore a first textured surface),
   the deposition, onto said first layer, of a second dielectric layer referred to as a smoothing layer, having a refractive index greater than or equal to that of the first layer, and that is made of an essentially amorphous material so as to sufficiently smooth the protrusions to form the textured outer surface,
the deposition, directly onto the smoothing layer, of an electrode in the form of layer(s), so as to form a surface substantially conforming to the smoothed outer surface.

Indeed, since protrusions that are too pointed, with angles that are too sharp, run the risk of causing an electrical contact between the anode and the cathode, which would thus degrade the OLED, the process incorporates a step of controlling the roughness.

Thus, according to the invention a surface texturing is obtained simply, via the first layer, and the profile is adjusted via the smoothing layer to provide the profile that is perfectly suited to the use of the structure in an OLED.

By being periodic, the grating of the prior art optimizes the increase in extraction efficiency around a certain wavelength but on the other hand does not promote white light emission; on the contrary, it has a tendency to select certain wavelengths and will emit for example more in the blue or in the red.

In contrast, the process according to the invention ensures a random texturing (preserved after smoothing) making it possible to increase the extraction efficiency across a wide range of wavelengths (no visible colorimetric effect), and provides an almost Lambertian angular distribution of the emitted light.

Moreover, the choice of the refractive index of the smoothing layer, by being greater than the refractive index of the substrate, makes it possible, in the use of the structure in an OLED for which the first electrode has a higher refractive index than that of the substrate, to generate less reflection of the light reaching the glass substrate, and on the contrary to promote the continuation of the path of the light through the substrate.

To define the smoothing of the textured outer surface, it is preferable to introduce a two-fold roughness criterion:
setting a maximum value for the well-known roughness parameter Rdq, which indicates the average slope; and
setting a maximum value, optionally in addition to a minimum value (so as to promote extraction), for the well-known roughness parameter Rmax, that indicates the maximum height.

Thus, in one preferred embodiment, the smoothed textured surface of the structure is defined by a roughness parameter Rdq of less than 1.5°, preferably less than 1°, or even less than or equal to 0.7°, and a roughness parameter Rmax of less than or equal to 100 nm, and preferably greater than 20 nm, over an analysis area of 5 μm by 5 μm, for example with 512 measurement points.

The analysis area is thus suitably chosen depending on the roughness to be measured. The roughness parameters of the surface are thus preferably measured using an atomic force microscope (AFM).

Another method of defining the smoothing of the outer surface is to say that the angle formed by the tangent with the normal to the substrate is greater than or equal to 30°, and preferably at least 45°, for the majority of the given points of this surface.

Preferably, for increased OLED reliability, at least 50%, or 70% and even 80% of the textured surface of the first dielectric layer which is to be covered with the active layer(s) of the OLED (so as to form one or more lighting regions), has an outer surface with submicron-sized texturing that is sufficiently smoothed (typically rounded, wavy) by the overlying smoothing layer according to the invention.

In other words, for a given number N of active light-emitting regions in an OLED, preferably at least 70%, or even at least 80% of the N active region(s) comprises a smoothed textured outer surface according to the invention.

For example, for simplicity of manufacture, the smoothing layer substantially covers the entirety of the first dielectric layer. The first dielectric layer may be substantially over the entire main face in question.

According to one feature, the first layer is deposited by a pyrolysis technique, especially in the gas phase (technique often denoted by the abbreviated CVD, for chemical vapor deposition), preferably at a temperature greater than or equal to 500° C., or in particular at low pressure by LPCVD (low pressure CVD), preferably at a temperature greater than or equal to 150° C. or even 200° C., or by magnetron sputtering.

This first layer comprises, preferably is constituted of, a layer deposited by CVD, for example of SnO₂ or SnZnₓO_{y}, or that is deposited by magnetron sputtering or LPCVD, for example of ZnO.

The advantage of using such a layer having per se roughness once deposited, is to improve the simplicity of manufacture, whereas the prior art U.S. 2004/0227462 requires, after the deposition of a specific layer on the substrate, a supplementary step of pressing the relief such as by embossing.

According to another feature, the smoothing layer may comprise, preferably is constituted of, a layer deposited by plasma-enhanced chemical vapor deposition (PECVD) which is a multidirectional deposition, with diffuse impacts, or as a variant a dielectric layer deposited by magnetron sputtering at a temperature of less than 100° C., preferably at room temperature.

The smoothing layer may comprise, or even is constituted of, a layer of Si₃N₄ deposited by PECVD or of TiO₂ deposited by PECVD, or a dielectric layer deposited by magnetron sputtering at a temperature of less than 100° C., preferably at room temperature, and which is chosen from SnO₂, SnZnO, AlN, TiN, NbN.

The use of Si₃N₄ may make it possible to constitute the first layer of a multilayer electrode, this material specifically being preferred as sublayer of the multilayer of the electrode since it forms a barrier to alkali metals. It is recalled that it is imperative to avoid the migration of alkali metals from the glass to the electrode (over time or during heat treatments for manufacturing the OLED) in order to prevent the electrode from oxidizing and deteriorating. Currently, when the electrode is formed, a barrier layer is systematically deposited beforehand on the glass substrate, in particular of Si₃N₄ type.

Advantageously, the deposition of the electrode in the form of layer(s), especially transparent conductive oxides and/or with at least one metallic layer (silver multilayer for example, between dielectric layers in particular), may be by physical vapor deposition, for example by magnetron sputtering, or by evaporation.

According to the invention, the process makes it possible to obtain an OLED device bearing a structure having a textured outer surface that forms the support of the organic light-emitting diode device, in particular obtained by the manufacturing process of the invention, the structure comprising, on a substrate made of inorganic glass:
a first textured dielectric layer, with protrusions, in the form of crystallites, having a thickness of at least 300 nm, preferably greater than 500 nm, or even greater than 1 μm, preferably with a refractive index greater than the refractive index of the glass substrate,
a second dielectric layer referred to as a smoothing layer, which is (essentially) amorphous, has a refractive index greater than or equal to that of the first layer, and is deposited directly onto said first layer, the smoothing layer being adapted in order to sufficiently smooth the protrusions and to form the textured outer surface,
   and the device comprising an electrode in the form of layer(s) forming deposit(s) conforming to the textured surface of the smoothing layer.

The textured outer surface may thus be defined by the roughness parameter Rdq of less than 1.5° and the roughness parameter Rmax of less than or equal to 100 nm over an analysis area of 5 μm by 5 μm, and/or the angle formed by the tangent of the smoothed textured surface with the normal to the glass substrate is greater than or equal to 30°, at a majority of points of the surface.

According to one feature, the textured first dielectric layer may typically have a roughness parameter RMS greater than or equal to 30 nm, or even greater than or equal to 50 nm over an analysis area of 5 μm by 5 μm.

The RMS (root mean square) parameter (or Rq), i.e. the quadratic mean deviation of the roughness, therefore quantifies the average height of the peaks and troughs in roughness, relative to the average height (thus an RMS roughness of 2 nm signifies an average peak amplitude of double that).

The surface of the smoothing layer may typically have a roughness parameter RMS greater than or equal to 30 nm and/or a roughness parameter Rmax greater than 20 nm, over an analysis area of 5 μm by 5 μm, for example with 512 measurement points.

The first electrode of the OLED, in the form of thin layer(s) intended to be deposited directly on the smoothing layer, may substantially conform to the surface (and thus preferably reproduce the texturing after leveling), for example it is deposited by vapor deposition and especially by magnetron sputtering or by evaporation.

The first electrode generally has an (average) index starting from 1.7 or even more (1.8, even 1.9). The organic layer(s) of the OLED generally have an (average) index starting from 1.8 or even more (1.9, even more).

The first layer and the smoothing layer deposited on the glass substrate are dielectric (in the sense of being non-metallic), preferably electrically insulating (in general having a bulk electrical resistivity, as known in the literature, of greater than 10⁹ □.cm) or semiconducting (in general having a bulk electrical resistivity, as known in the literature, of greater than 10⁻³ □.cm and less than 10⁹ □.cm).

Preferably, the first layer and/or the smoothing layer:
are essentially inorganic, especially so as to have a good heat resistance;
and/or do not noticeably alter the transparency of the substrate; for example, the substrate coated with the first (and even with the smoothing layer) may have a light transmission T_{L} greater than or equal to 70%, preferably greater than or equal to 80%.

The first layer on the glass substrate advantageously has a refractive index greater than the refractive index of the glass substrate.

The first layer may comprise, or even be constituted of, a layer of SnO₂, ZnO or SnZnₓO_{y}.

Advantageously, the smoothing layer comprises, or even is constituted of, an essentially inorganic layer, preferably made of at least one of the following materials: Si₃N₄, TiO₂ or ZnO, Sn0₂, SnZnO, AlN, TiN or NbN.

The thickness of the smoothing layer may be at least 100 nm, preferably less than 1 μm, or even less than 500 nm.

According to one feature, the structure comprises an electrode in the form of layer(s) forming deposit(s) that conform to the underlying textured surface (surface of the smoothing layer).

A low-cost, industrial glass, for example a silicate, especially a soda-lime-silica glass, is preferably chosen. The refractive index is conventionally about 1.5. A high-index glass may also be chosen.

A final subject of the invention is an organic light-emitting diode (OLED) device incorporating the structure obtained by the process of the invention or defined previously, the textured surface of the structure being arranged on the side of the organic light-emitting layer(s) (OLED system), i.e. inside the device, on the side opposite the face emitting light to outside of the device, the structure having a textured outer surface being under a first electrode underlying the organic light-emitting layer(s).

The OLED may form a lighting panel, or a backlight (substantially white and/or uniform) especially having a (solid) top-electrode area greater than or equal to 1×1 cm², or even as large as 5×5 cm² and even 10×10 cm² or larger.

Thus, the OLED may be designed to form a single lighting area (with a single electrode area) emitting (substantially white) polychromatic light or a multitude of lighting areas (having a plurality of electrode areas) emitting (substantially white) polychromatic light, each lighting area having a (solid) electrode area greater than or equal to 1×1 cm², or even 5×5 cm², 10×10 cm² or larger.

Thus in an OLED according to the invention, especially for lighting, it is possible to choose a nonpixelated electrode. This differs from a display-screen (LCD, etc.) electrode that is formed from three juxtaposed, generally very small, pixels, each emitting a given, almost monochromatic light (typically red, green or blue).

The OLED system, on top of the bottom electrode as defined previously may be able to emit a polychromatic light defined, at 0°, by the (x1, y1) coordinates of the XYZ 1931 CIE color diagram, coordinates given therefore for light incident at a right angle.

The OLED may be bottom-emitting and optionally also top-emitting depending on whether the top electrode is reflective or, respectively, semireflective or even transparent (especially having a T_{L} comparable to the anode, typically greater than 60% and preferably greater than or equal to 80%).

The OLED may furthermore comprise a top electrode on top of said OLED system.

The OLED system may be able to emit (substantially) white light, having coordinates as close as possible to (0.33; 0.33) or (0.45; 0.41), especially at 0°.

To produce substantial white light several methods are possible: component (red, green and blue emission) mixture in a single layer; a multilayer, on the face of the electrodes, of three organic structures (red, green and blue emission) or of two organic structures (yellow and blue).

The OLED may be able to produce as output (substantially) white light, having coordinates as close as possible to (0.33; 0.33) or (0.45; 0.41), especially at 0°.

The OLED may be part of a multiple glazing unit, especially glazing having a vacuum cavity or a cavity filled with air or another gas. The device may also be monolithic, comprising a monolithic glazing pane so as to be more compact and/or lighter.

The OLED may be bonded, or preferably laminated using a lamination interlayer, with another planar substrate, called a cap, which is preferably transparent, such as glass, especially an extra-clear glass.

The invention also relates to the various applications that may be found for these OLEDs, used to form one or more transparent and/or reflective (mirror function) light-emitting surfaces placed externally and/or internally.

The device may form (alternatively or cumulatively) a lighting system, a decorative system, or an architectural system etc., or a display or signaling panel, for example a design, logo or alphanumeric sign, especially an emergency exit sign.

The OLED may be arranged so as to produce a uniform polychromatic light, especially for a uniform lighting, or to produce various light-emitting regions, having the same intensity or different intensities.

When the electrodes and the organic structure of the OLED are chosen to be transparent, it is possible especially to produce a light-emitting window. The improvement in the illumination of the room is then not produced to the detriment of the transmission of light.

Furthermore, by limiting reflection of light, especially from the external side of the light-emitting window, it is also possible to control the reflectance level for example so as to meet anti-dazzle standards in force for the curtain walling of buildings.

More widely, the device, especially transparent in part(s) or everywhere, may be:
intended for use in a building, such as for a light-emitting external glazing unit, a light-emitting internal partition or a (or part of a) light-emitting glazed door, especially a sliding door;
intended for use in a means of transport, such as for a light-emitting roof, a (or part of a) light-emitting side window, a light-emitting internal partition for a terrestrial, maritime or aerial vehicle (automobile, lorry, train, airplane, boat, etc.);
intended for use in a domestic or professional setting such as for a bus shelter panel, a wall of a display cabinet, a jeweler's display case or a shop window, a wall of a greenhouse, a light-emitting tile;
intended for use as an internal fitting, such as for a shelf or furniture element, a front face for an item of furniture, a light-emitting tile, a ceiling light or lamp, a light-emitting refrigerator shelf, an aquarium wall; or
intended for backlighting of a piece of electronic equipment, especially a display screen, optionally a double screen, such as a television or computer screen or a touch screen.

OLEDs are generally separated into two broad families depending on the organic material used.

If the light-emitting layers are formed from small molecules, SM-OLEDs (small molecule light-emitting diodes) are spoken of.

Generally, the structure of an SM-OLED consists of a hole-injection-layer (HIL) multilayer, a hole transporting layer (HTL), a light-emitting layer and an electron transporting layer (ETL).

Examples of organic light-emitting multilayers are for example described in the document entitled “Four-wavelength white organic light-emitting diodes using 4,4′-bis-[carbazoyl-(9)]-stilbene as a deep blue emissive layer” C. H. Jeong et al., published in Organic Electronics, 8 (2007), pages 683-689.

If the organic light-emitting layers are polymers, PLEDs (polymer light-emitting diodes) are spoken of.

The present invention is now described using uniquely illustrative examples that in no way limit the scope of the invention, and using the appended drawings, in which:

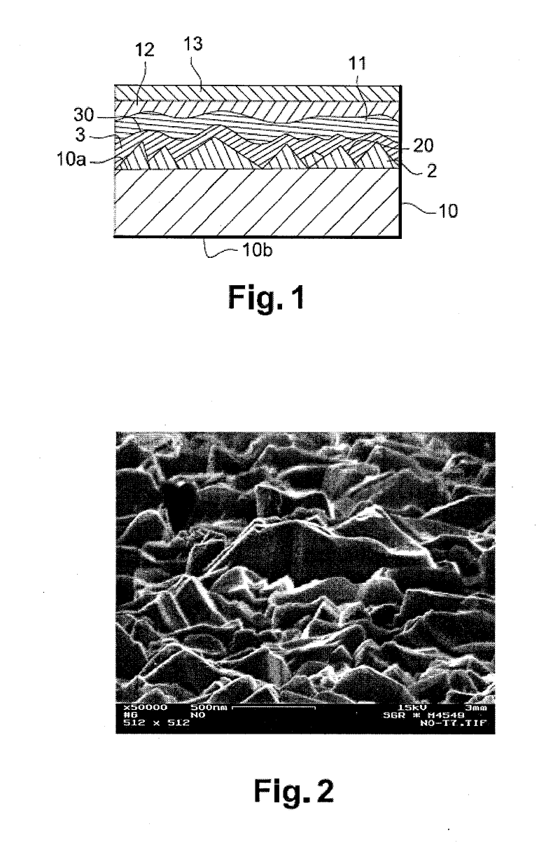

FIG. 1 shows a schematic cross-sectional view of an OLED, the glass of which bears a first textured layer and a second smoothing layer in accordance with the manufacturing process of the invention; and

FIG. 2 is an SEM view of the surface of the first textured layer.

FIG. 1, which is not to scale so as to be more easily understood, shows an organic light-emitting diode device 1 that comprises in succession:
a structure having a textured outer surface 30 formed
from a glass 10, for example soda-lime-silica glass, which comprises two opposite faces 10a and 10b, the face 10a being arranged facing the first electrode 11;
a first transparent layer 2 deposited so as to form protrusions, and therefore a first textured surface 20;
and a second transparent layer 3 capable of smoothing the surface 20, and of forming a textured outer surface 30;
a first transparent electrically-conductive coating 11 that forms a first electrode (generally referred to as the anode), having a surface that conforms to the surface 30,
a layer 12 of organic material(s),
a second electrically-conductive coating 13 which forms a second electrode, and has, preferably facing the organic layer 12, a (semi) reflective surface (intended to send the light emitted by the organic layer toward the opposite direction, that of the transparent substrate 10).

The inventors have demonstrated that it is paramount for the outer surface of the structure that must receive the electrode to be free from any sharp points.

Therefore, to guarantee that this requirement is met, it is possible to choose a smoothing layer with a textured surface defined by a roughness parameter Rdq of less than 1.5°, and a roughness parameter Rmax of less than or equal to 100 nm over an analysis area of 5 μm by 5 μm, preferably by AFM.

The tangent to most points of the textured surface may also form, with the normal to the planar opposite face, an angle of greater than or equal to 30°, and preferably at least 45°.

The textured outer surface may also be defined by a roughness parameter Rmax of greater than or equal to 20 nm over an analysis area of 5 μm by 5 μm, by AFM.

The first layer 2 is deposited directly onto the glass 10 at a temperature greater than or equal to 100° C., with a thickness greater than 300 nm and with a deposition method suitable for forming nanoscale protrusions, typically crystallites.

The constituent material of the first layer 2 has, for example, a refractive index that is substantially different and greater than that of the glass 10, having a variation of the order of 0.4. It is, for example, SnO₂ (undoped) having a refractive index of 1.9, or else ZnO having an index of 1.9.

The material, once deposited, makes it possible to obtain protrusions (large crystallites) giving a surface having a parameter RMS of at least 50 nm, for example over a thickness of 1.4 μm.

The surface of such a layer 2 as a function of the thickness y is shown in FIG. 2.

As a variant, a layer of ZnO deposited by high- temperature magnetron sputtering or by high-temperature LPCVD is chosen as the first layer. For the LPCVD deposition conditions, it is possible, for example, to go by the publication entitled “Rough ZnO layers by LP-CVD process and their effect in improving performances of amorphous microcrystalline silicon solar cells” by S. Fay et al., Solar Energy Materials & Solar Cells, 90 (2006), pages 2960-2967, without doping the ZnO.

As a counter-example, a layer of ZnO deposited at room temperature has an RMS of the order of 2 nm.

Starting from 100° C., for example for 700 nm, a ZnO layer according to the invention has an RMS of around 10 nm.

As another variant, a layer of SnZnO deposited by high-temperature CVD is chosen as the first layer.

FIG. 2 is a scanning electron microscope (SEM) view along an angle of 15 with a magnification of 50 000 of the surface of the first textured layer 2 made of SnO₂ by CVD deposition.

The deposition conditions for this layer 2 are described here. In a reactor through which the substrate passes at 20 cm/min, on a glass plate having a thickness of 3 mm heated at 590° C., the following are sprayed through a 40 cm-long nozzle onto the glass: oxygen precursors at 7.5 l/min, 3.1 l/min of carrier nitrogen, entraining monobutyl trichloro tin vapors heated at 150° C., 51 cm³/min of carrier nitrogen entraining trifluoroacetic acid vapors cooled to 5° C., and 8 l/min of carrier nitrogen entraining water vapors heated to 40° C.

The smoothing layer 3 is, for example, a layer of Si₃N₄ which covers the first layer 2. Its thickness is, for example, 400 nm. This layer sufficiently levels the protrusions in order to obtain the textured surface, the profile of which was characterized above.

Furthermore, the constituent material of the smoothing layer 3 has a higher refractive index than that of the first textured layer 2, preferably between 1.8 and 2.0.

The Si₃N₄ layer is deposited by PECVD with a cathode supplied at a radiofrequency of 13.56 MHz, a pressure of 150 mTorr and at room temperature, with precursors of silane (SiH₄) at 37 sccm, ammonia (NH₃) at 100 sccm and helium at 100 sccm, and with a deposition lasting 30 minutes.

More preferably still, the smoothing layer 3 has a refractive index less than or equal to the (average) index of the first electrode (typically of 1.9-2).

As a variant, a layer of TiO₂ is chosen as the smoothing layer 3.

Moreover, it is preferred to produce the first electrode 11 by one or more standard deposition technique(s), typically by vapor deposition(s), in particular magnetron sputtering or by evaporation.

As the first electrode, a transparent conductive oxide layer is for example chosen: ITO having a thickness of around 100 nm or else a silver-containing multilayer (silver between dielectric layers in particular), for example as described in documents WO 2008/029060 and WO 2008/059185.

The multilayer of the electrode 11 comprises, for example:
an optional base layer (and/or) a wet-etch-stop layer which may be the Si₃N₄ already deposited;
an optional mixed-oxide sublayer based on, optionally doped, zinc and tin or a mixed indium and tin oxide (ITO) layer or a mixed indium and zinc oxide (IZO) layer;
a contact layer based on a metal oxide chosen from ZnOₓ whether doped or not, Sn_{y}Zn_{z}Oₓ, ITO or IZO;
a functional metal layer, for example containing silver, that is intrinsically electrically conductive;
an optional thin overblocker layer directly on the functional layer, the thin blocker layer comprising a metal layer having a thickness less than or equal to 5 nm and/or a layer having a thickness less than or equal to 10 nm, which is based on a substoichiometric metal oxide, a substoichiometric metal oxynitride, or a substoichiometric metal nitride (and optionally a thin underblocker layer directly below the functional layer);
an optional protective layer chosen from ZnOₓ, Sn_{y}Zn_{z}Oₓ, ITO or IZO; and
an overlayer based on a metal oxide for matching the work function of said electrode coating.

It is possible for example to choose as the multilayer:

ZnO:Al/Ag/Ti or NiCr/ZnO:Al/ITO, having respective thicknesses of 5 to 20 nm for the ZnO:Al, 5 to 15 nm for the silver, 0.5 to 2 nm for the Ti or NiCr, 5 to 20 nm for the ZnO:Al and 5 to 20 nm for the ITO.

It is possible to arrange, on the optional base layers and/or wet etch-stop layers and/or sublayers, n times the following structure, where n is an integer greater than or equal to 1:
the contact layer; optionally the thin underblocker layer;
the functional layer;
the thin overblocker layer; and
optionally the layer protecting against water and/or oxygen.

The final layer of the electrode is still the overlayer.

The process consists of:
step a): depositing onto the glass 10 a first transparent layer 2, preferably by the CVD technique for SnO₂ or SnZnₓO, by magnetron sputtering or LPCVD for ZnO, so as to form protrusions, the layer having a thickness between 300 and 2000 nm, preferably 500 to 1500 nm;
step b): depositing on this first layer 2, preferably by PECVD for Si₃N₄, a second layer 3 referred to as a smoothing layer, in particular due to its amorphous nature, having a thickness which is between, for example, 100 and 500 nm, in order to have at the surface 30, a profile which corresponds to the particular criteria of the glass-electrode interface in an OLED; and
step c): depositing the electrode in a conforming manner.

1. A process for manufacturing an organic light-emitting diode device bearing a structure having a textured outer surface comprising a substrate made of inorganic glass that forms the support of the organic light-emitting diode device, comprising:
manufacturing said structure having a textured outer surface, the manufacturing comprising:
vapor depositing, onto the substrate made of inorganic glass, of a first dielectric layer of at least 300 nm in thickness at a temperature greater than or equal to 100° C. so as to form protrusions,
depositing onto said first layer a smoothing layer, the smoothing layer being a dielectric layer, having a refractive index greater than or equal to that of the first layer, and made of an essentially amorphous material so as to sufficiently smooth the protrusions and to form the textured outer surface,
depositing, directly onto the smoothing layer, an electrode including one or more layers, so as to form a surface that conforms substantially to the smoothed outer surface.

2. The process as claimed in claim 1, wherein the deposition of the smoothing layer is such that the textured outer surface is defined by a roughness parameter Rdq of less than 1.5°, and a roughness parameter Rmax of less than or equal to 100 nm over an analysis area of 5 μm by 5 μm.

3. The process as claimed in claim 1, wherein the first layer forming the protrusions is deposited by at least one of the following deposition methods: CVD chemical deposition, LPCVD low pressure chemical deposition, or by magnetron sputtering.

4. The process as claimed in claim 1, wherein the first layer comprises a layer of SnO₂ deposited by CVD, or a layer of ZnO deposited by magnetron sputtering or LPCVD, or a layer of SnZnₓO_{y} deposited by CVD.

5. The process as claimed in claim 1, wherein the smoothing layer comprises a layer deposited by plasma-enhanced chemical vapor deposition (PECVD) or comprises a dielectric layer deposited by magnetron sputtering at a temperature of less than 100° C.

6. The process as claimed in claim 1, wherein the smoothing layer comprises Si₃N₄ deposited by PECVD or TiO₂ deposited by PECVD, or comprises a dielectric layer deposited by magnetron sputtering at a temperature of less than 100° C., and which is chosen from SnO₂, SnZnO, AlN, TiN and NbN.

7. The manufacturing process as claimed in claim 1 wherein deposition of the electrode, is by physical vapor deposition.

8. An organic light-emitting diode device bearing a structure having a textured outer surface that forms the support of the organic light-emitting diode device, capable of being obtained by the manufacturing process as claimed in claim 1, the structure comprising, on a substrate made of inorganic glass:
a first textured dielectric layer, with protrusions, in the form of crystallites, having a thickness of at least 300 nm,
a smoothing layer, the smoothing layer being a dielectric layer that is amorphous, has a refractive index greater than or equal to that of the first layer, and is deposited directly onto said first layer, the smoothing layer being adapted to sufficiently smooth the protrusions and to form a textured outer surface,
and
an electrode including one or more layers forming deposit(s) conforming to the textured surface of the smoothing layer.

9. The organic light-emitting diode device as claimed in claim 8, wherein the textured outer surface is defined by a roughness parameter Rdq of less than 1.5° and a roughness parameter Rmax of less than or equal to 100 nm over an analysis area of 5 μm by 5 μm, and/or wherein an angle formed by a tangent of the smoothed textured surface with a normal to the glass substrate is greater than or equal to 30°, at a majority of points of the surface.

10. The organic light-emitting diode device as claimed in claim 8, wherein the surface of the smoothing layer is defined by a roughness parameter RMS greater than or equal to 30 nm and/or a roughness parameter Rmax greater than 20 nm, over an analysis area of 5 μm by 5 μm.

11. The organic light-emitting diode device as claimed in claim 10 wherein the first layer has a refractive index greater than the refractive index of the glass substrate.

12. The organic light-emitting diode device as claimed in claim 8, wherein the first layer comprises, or is constituted of, a layer of SnO₂, of ZnO or of SnZnₓO_{y}.

13. The organic light-emitting diode device as claimed in claim 8, wherein the smoothing layer comprises, or is constituted of, an essentially inorganic layer, made of at least one of the following materials: Si₃N₄, TiO₂, ZnO, SnO₂, SnZnO, AlN, TiN, NbN.

14. The organic light-emitting diode device as claimed in claim 8, wherein a thickness of the smoothing layer is at least 100 nm.

15. The organic light-emitting diode device as claimed in claim 8, wherein the first electrode is subjacent to one or more organic light-emitting layers.

16. The organic light-emitting diode device obtained by the process as claimed in claim 1.

17. The process as claimed in claim 5, wherein the dielectric layer is deposited by magnetron sputtering at room temperature.

18. The process as claimed in claim 6, wherein the dielectric layer is deposited by magnetron sputtering at room temperature.

19. The organic light-emitting diode device as claimed in claim 14, wherein the thickness of the smoothing layer is less than 1 μm.
